(19) United States
(12) Patent Application Publication
(10) Pub. No.: US 2020/0075510 A1
(43) Pub. Date: Mar. 5, 2020

(54) SEMICONDUCTOR PACKAGE AND MANUFACTURING METHOD THEREOF

(71) Applicant: Powertech Technology Inc., Hsinchu County (TW)

(72) Inventors: Shang-Yu Chang Chien, Hsinchu County (TW); Hung-Hsin Hsu, Hsinchu County (TW); Nan-Chun Lin, Hsinchu County (TW)

(73) Assignee: Powertech Technology Inc., Hsinchu County (TW)

(21) Appl. No.: 16/116,915

(22) Filed: Aug. 30, 2018

(51) Int. Cl. H01L 23/64; H01L 23/31; H01L 23/498; H01L 23/00; H01L 49/02; H01L 21/56; H01L 21/48; H01L 21/78

(52) U.S. Cl. CPC H01L 23/642; H01L 23/3128; H01L 23/49822; H01L 23/49827; H01L 23/49816; H01L 24/08; H01L 2224/08225; H01L 21/568; H01L 21/4857; H01L 21/486; H01L 21/561; H01L 21/78; H01L 28/40

(57) ABSTRACT

A semiconductor package including a semiconductor die, an insulating encapsulant, a passive component, such as a thin film capacitor, and a redistribution structure is provided. The semiconductor die includes an active surface and a plurality of conductive pads disposed on the active surface. The insulating encapsulant encapsulates the semiconductor die and exposes the active surface of the semiconductor die. The passive component is disposed on the active surface of the semiconductor die. The redistribution structure is disposed on the active surface of the semiconductor die electrically connected to the conductive pads of the semiconductor die and the passive component. A manufacturing method of a semiconductor package is also provided.

### BACKGROUND OF THE INVENTION

### Field of the Invention

The disclosure relates to a semiconductor package and a manufacturing method, in particular, to a semiconductor package having an embedded passive component and a manufacturing method thereof.

### Description of Related Art

As technology has advanced, electronic products have been designed to become lighter, slimmer, shorter, and smaller, with the aim of developing products smaller in volume, lighter in weight, higher in integration, and therefore more competitive in the market. However, as these products gradually shrink in volume, electronic circuitry and components are arranged at increasingly higher densities, and operation of the electronic components may cause electrical noise that needs to be protected from in order to avoid disruption to the operation of or damage to the semiconductor die. One way to protect from such disruption and damage is to employ a capacitor close to the semiconductor die, in order to provide a path to ground for the high frequency noise. However, this passive component occupies extra space adjacent to the semiconductor die, which one could minimize for further miniaturization. As a result, maintaining the reliability and the functionality of the semiconductor package while continuing to miniaturize the semiconductor package has become a challenge to researchers in the field.

### SUMMARY OF THE INVENTION

Accordingly, the disclosure is directed to a semiconductor package having an embedded passive component and a manufacturing method thereof, which can enhance the reliability thereof, while occupying a minimum of space due to the embedded nature of the passive component.

The disclosure provides a semiconductor package including a semiconductor die, an insulating encapsulant, a passive component, such as a thin film capacitor and a redistribution structure. The semiconductor die includes an active surface and a plurality of conductive pads disposed on the active surface. The insulating encapsulant encapsulates the semiconductor die and exposes the active surface of the semiconductor die. The passive component is disposed on the active surface of the semiconductor die. The redistribution structure is disposed on the active surface of the semiconductor die and electrically connected to the conductive pads of the semiconductor die and the passive component.

The disclosure provides a manufacturing method of a semiconductor package. The method includes at least the following steps. A passive component is disposed on an active surface of a semiconductor die, wherein the semiconductor die includes a plurality of conductive pads disposed on the active surface. The semiconductor die is encapsulated with an insulating encapsulant, wherein the insulating encapsulant exposes the active surface of the semiconductor die. A redistribution structure is formed on the active surface of the semiconductor die, wherein the redistribution structure is electrically connected to the conductive pads of the semiconductor die and the passive component.

Based on the above, the passive component is embedded in the semiconductor package. Accordingly, the space occupied by the passive component is less than if the passive component were not embedded.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the disclosure. The ratios of sizes and dimensions of one depicted component to another do not necessarily reflect the actual proportions of the components relative to each other. For example, the passive component has been enlarged in the drawings for clarity.

FIGS. 1A to 1D are schematic cross-sectional views illustrating a manufacturing method of a semiconductor die having a passive component according to an embodiment of the disclosure.

FIGS. 2A to 2I are schematic cross-sectional views illustrating a manufacturing method of a semiconductor package according to an embodiment of the disclosure.

FIGS. 3A to 3D are cross-sectional views illustrating alternative steps of a manufacturing method of a semiconductor package according to an embodiment of the disclosure.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

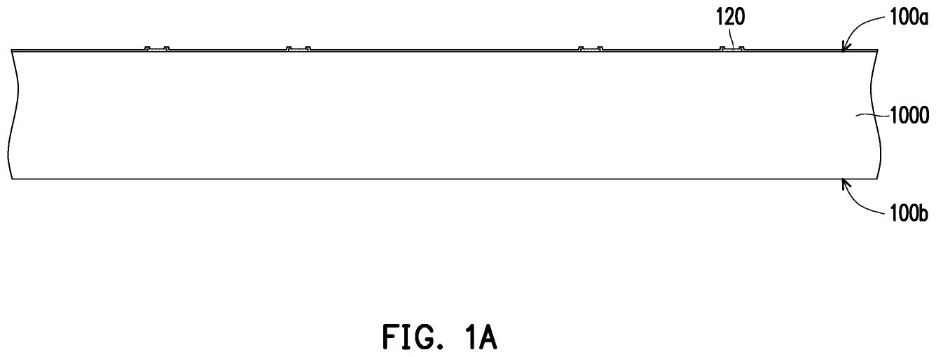

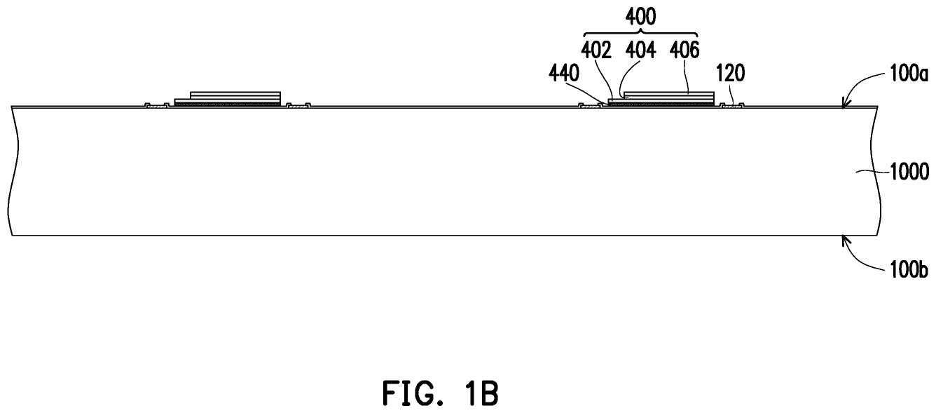

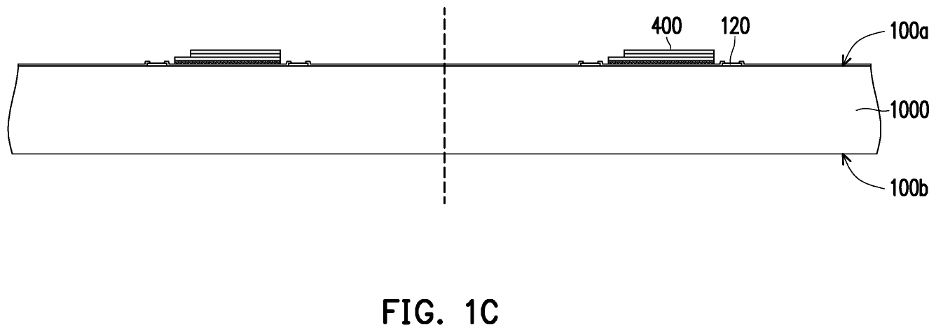

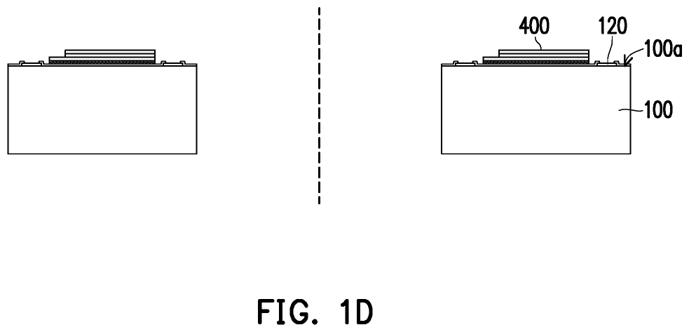

FIGS. 1A to 1D are schematic cross-sectional views illustrating a manufacturing method of a semiconductor die having a passive component according to an embodiment of the disclosure. Referring to FIG. 1A, a semiconductor wafer 1000 is provided. The semiconductor wafer 1000 may have an active surface 100a and a back surface 100b opposite to the active surface 100a. The semiconductor wafer 1000 may include a plurality of dies, and a plurality of conductive pads 120 may be disposed on the active surface 100a of each die of the semiconductor wafer 1000. In some embodiments, the conductive pads 120 may be correspondingly disposed before the dies are separated from each other, but the method is not limited thereto. The semiconductor wafer 1000 may be made of silicon, polymer, or other suitable materials.

Referring to FIG. 1B, at least one passive component 400 is disposed on the active surface 100a of each of the dies of the semiconductor wafer 1000. In some embodiments, the passive component 400 may be correspondingly disposed before the dies are separated from each other, but the method is not limited thereto. The passive component 400 may be disposed on the active surface 100a without covering the conductive pads 120. For example, each passive component 400 may be disposed on the active surface 100a between the adjacent conductive pads 120 one by one through pick-and-place method. For example, the region of the active surface 100a where the passive component 400 is disposed is populated by (or free of) by the contact pads 120. The passive component 400 may be surrounded by the conductive pads 120. The passive component 400 may be attached to the active surface 100a of semiconductor wafer 1000 through an adhesive layer 440. For example, the adhesive layer 440 may be a die attach film (DAF), or other suitable adhesive materials. The passive component 400 may be capacitor, inductor, resistor, or other suitable passive component. For example, the passive component 400 may be a thin-film passive component and may include a first electrode layer 402, a thin-dielectric layer 404 and a second electrode layer 406 sequentially stacked on top of each other. In some embodiments, the thickness of the passive component 400 may be less than 5 μm.

Referring to FIG. 1C and FIG. 1D, after disposing the passive component 400, the semiconductor wafer 1000 may be singulated to form a plurality of semiconductor dies 100 which are illustrated in FIG. 1D. The semiconductor dies 100 are, for example, an ASIC (Application-Specific Integrated Circuit). However, it construes no limitation in the invention. Other suitable active devices may also be utilized as the semiconductor dies 100. In some embodiments, before performing singulation, the profile of the semiconductor wafer 1000 may be reduced to a desired thickness according to the design requirement. For example, the back surface 100b of the semiconductor wafer 1000 may be grinded to reduce the thickness thereof by a mechanical grinding process, a chemical mechanical polishing (CMP) process, or other suitable process. The passive component 400 may alternatively be disposed on the semiconductor die 100 after singulation, and the detailed descriptions will be described later in other embodiments.

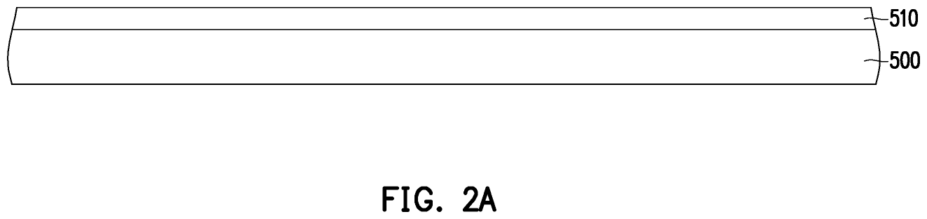

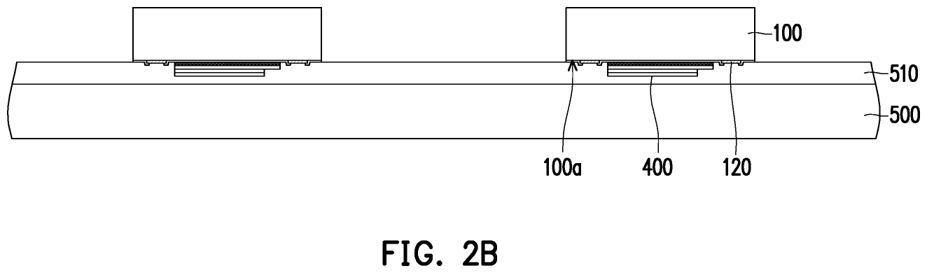

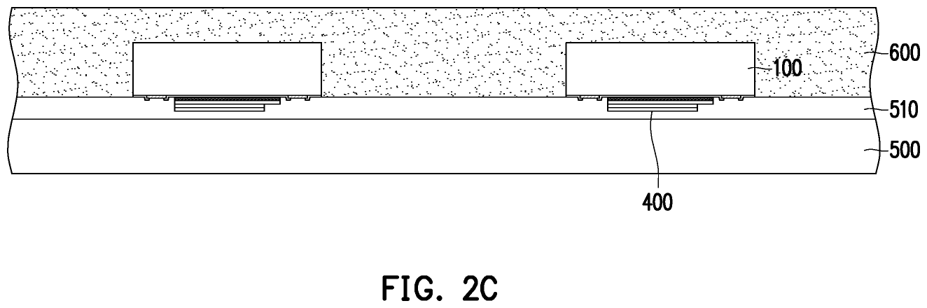

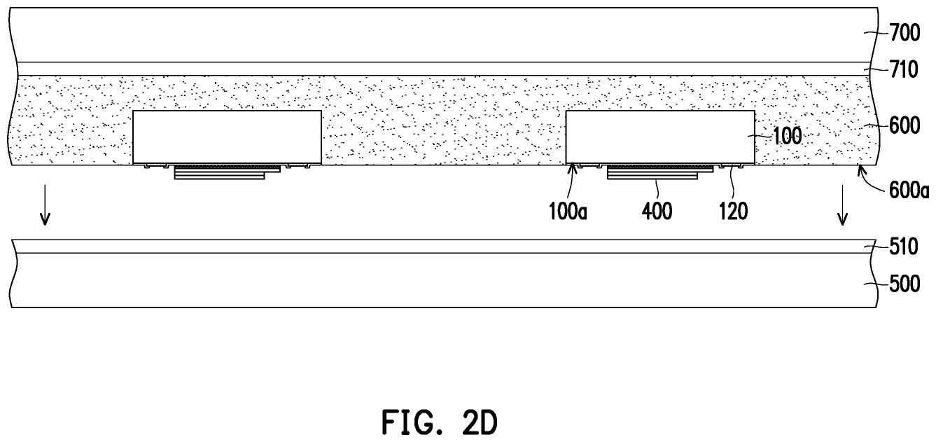

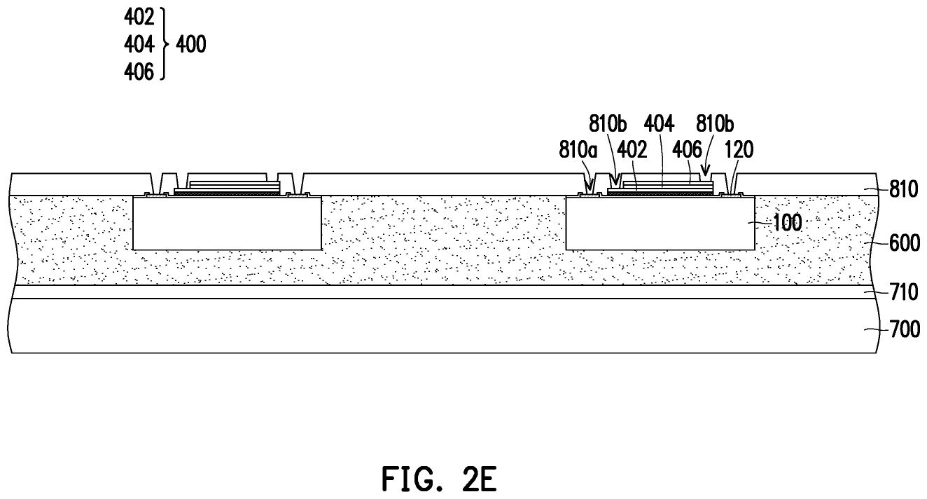

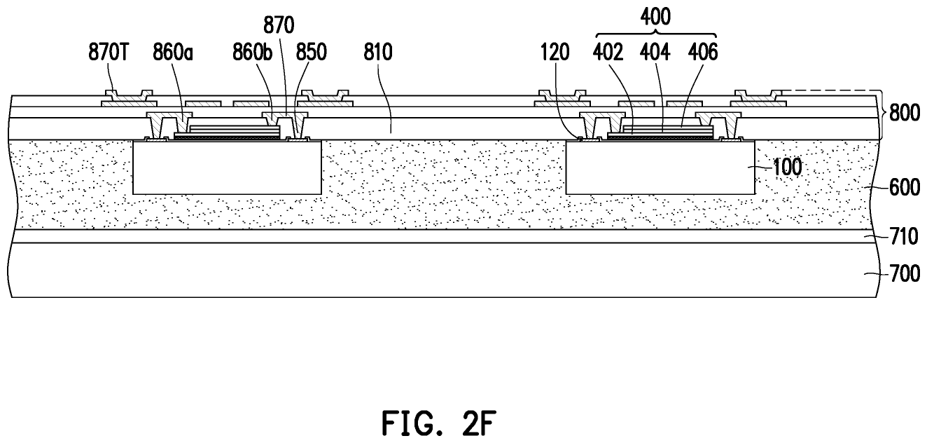

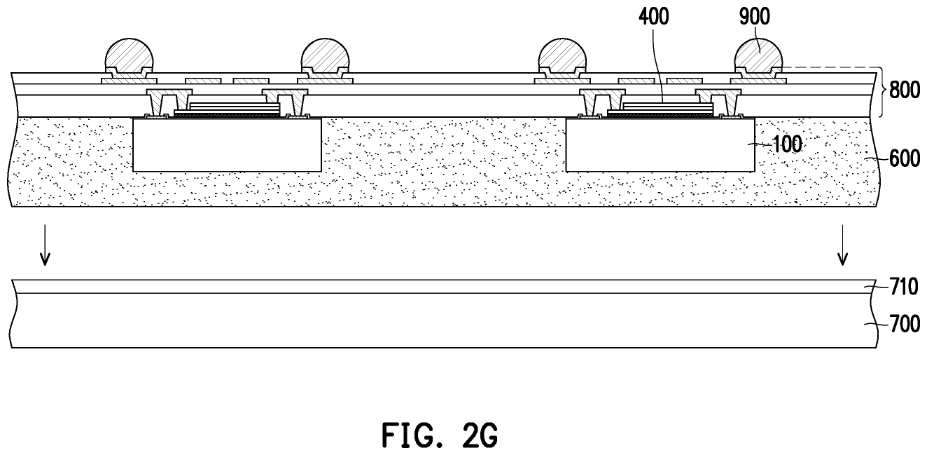

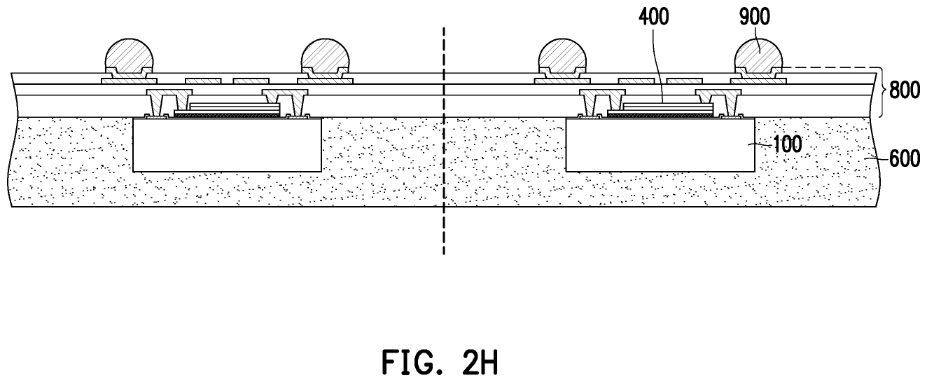

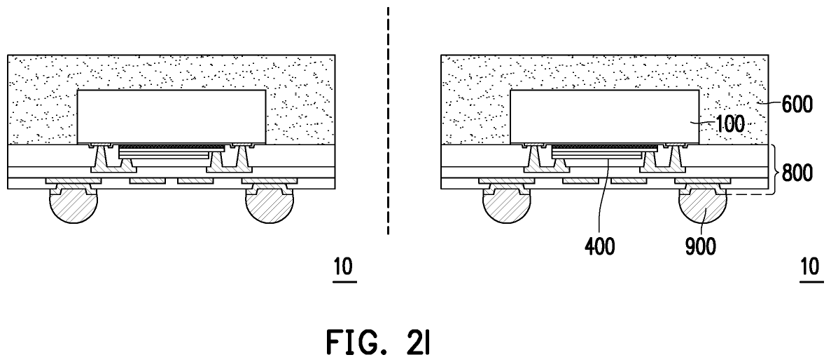

FIGS. 2A to 2I are schematic cross-sectional views illustrating a manufacturing method of a semiconductor package according to an embodiment of the disclosure. FIGS. 2A to 2D relate to an encapsulation of the semiconductor dies 100. Referring to FIG. 2A, a first temporary carrier 500 is provided. In some embodiments, a first release layer 510 may be formed on the first temporary carrier 500. The first release layer 510 may be a liquid-type release layer, a light-to-heat-conversion (LTHC) layer, or other suitable release layers. Referring to FIG. 2B, the semiconductor dies 100 may be disposed on the first temporary carrier 500. The active surface 100a of the semiconductor die 100 may face toward the first temporary carrier 500. After disposing the semiconductor die 100, the conductive pads 120 of the semiconductor die 100 may be covered by the first release layer 510. The passive component 400 disposed on the active surface 100a of the semiconductor die 100 may be partially covered by the first release layer 510 or embedded in the first release layer 510 depending on the bonding force applied to the semiconductor die 100.

Referring to FIG. 2C, after disposing the semiconductor die 100 on the first temporary carrier 500, an insulating encapsulant 600 may be formed on the first temporary carrier 500 to encapsulate the semiconductor die 100. In some embodiments, the thickness of the insulating encapsulant 600 may be greater than the thickness of the semiconductor die 100. The insulating encapsulant 600 may be epoxy molding compound (EMC) forming by a molding process, or other suitable material providing protection from moisture, oxygen, heat, and shock. After forming the insulating encapsulant 600, a thinning process is optionally performed to reduce the thickness of the insulating encapsulant 600. The thinning process may be a mechanical grinding process, a CMP process, or other suitable process. The thinning process may be conducive to reduce the overall height of the package structure and also improve heat generated by the semiconductor die 100 to dissipate to the ambient.

Referring to FIG. 2D, after encapsulation, a second temporary carrier 700 may, optionally, be provided on the insulating encapsulant 600 opposite to the active surface 100a of the semiconductor die 100. In some embodiments, a second release layer 710 may be disposed between the second temporary carrier 700 and the insulating encapsulant 600 to enhance the releasibility therebetween. In some embodiments, the first temporary carrier 500 may be removed to expose the active surface 100a of the semiconductor die 100. For example, the external energy such as UV laser, visible light or heat, may be applied to the first release layer 510 so that the first temporary carrier 500 may be peeled off from the insulating encapsulant 600. After removing the first temporary carrier 500, the passive component 400 and the conductive pads 120 may be exposed. A surface 600a of the insulating encapsulant 600 may be coplanar with the active surface 100a of the semiconductor die 100.

FIGS. 2E to 2F illustrates the method of forming a redistribution structure 800 on the active surface 100a of the semiconductor die 100. A dielectric layer 810 including a plurality of first openings 810a may be formed on the insulating encapsulant 600. A dielectric layer 810 may be formed over the insulating encapsulant 600 to cover the active surface 100a of the semiconductor die 100. The dielectric layer 810 may have a plurality of first openings 810a and a plurality of second openings 810b. The first openings 810a may expose at least a portion of the conductive pads 120 of the semiconductor die 100. The second openings 810b may expose at least a portion of the first electrode layer 402 and at least a portion of the second electrode layer 406 of the passive component 400. The first openings 810a may be deeper than the second openings 810b. The dimensions of the first openings 810a and the second openings 810b may be the same or different depending on the design requirement, which is not limited thereto.

Subsequently, a conductive material (e.g. copper, aluminum, nickel, or other suitable conductive materials) may be formed on the dielectric layer 810 and inside the first openings 810a and the second openings 810b by a deposition process, a plating process, or other suitable process. The conductive material formed in the first openings 810a and the second openings 810b may be referred as the first conductive vias 850 and the second conductive vias 860a and 860b, respectively. The thickness of each first conductive via 850 may be greater than the thickness of each second conductive via 860a and 860b. The first conductive vias 850 are embedded in the dielectric layer 810 and electrically coupled to the conductive pads 120 of the semiconductor die 100 directly. The second conductive vias 860a and 860b are embedded in the dielectric layer 810 and electrically coupled to the first electrode layer 402 and the second electrode layer 406 of the passive component 400 directly. Next, the conductive material formed on the dielectric layer 810 may be patterned by a photolithography and etching process to form a conductive pattern 870. The conductive pattern 870 is electrically connected to the first conductive vias 850 and the second conductive vias 860a and 860b. The redistribution structure 800 may be referred as a fan-out redistribution structure in which the conductive pattern 870 connected to the semiconductor die 100 is rearranged and expanded wider than the size of the semiconductor die.

The abovementioned steps may be performed multiple times to obtain a multi-layered redistribution structure 800 as required by the circuit design. In some embodiments, the topmost dielectric layer 810 may then have openings exposing at least the portion of the topmost conductive pattern 870T for further electrical connection. In some embodiments, the topmost conductive pattern 870T may be referred as the under-ball metallurgy (UBM) patterns for the subsequent ball mounting process.

Referring to FIG. 2G, after forming the redistribution structure 800, a plurality of conductive terminals 900 are formed on the redistribution structure 800 opposite to the insulating encapsulant 600. For example, the conductive terminals 900 may be solder balls formed on the topmost conductive pattern 870T through a ball placement process. In some embodiments, the conductive terminals 900 may include conductive pillars, conductive bumps or a combination thereof formed by a plating process, or other suitable process. However, it construes no limitation in the disclosure. Other possible forms and shapes of the conductive terminals 900 may be utilized according to the design requirement. A soldering process and a reflowing process may be optionally performed for enhancement of the adhesion between the conductive terminals 900 and the redistribution structure 800.

In some embodiments, after forming the conductive terminals 900, the second temporary carrier 700 may be removed from the insulating encapsulant 600 by, for example, peeling off the release layer 710. The removing process of the second temporary carrier 700 may be similar as the removing process of the first temporary carrier 500 described in FIG. 2D, and the detailed descriptions are omitted for brevity. After removing the second temporary carrier 700, a heat sink may be optionally disposed on the exposed surface of the insulating encapsulant 600 opposite to the redistribution structure 800.

Referring to FIGS. 2H and 2I, after removing the second temporary carrier 700, a singulation process may be performed and the manufacturing process of a semiconductor package 10 is substantially completed. Since the passive component 400 disposed on the active surface 100a of the semiconductor die 100 is embedded in the redistribution structure 800 and electrically coupled to the semiconductor die 100 and the redistribution structure 800, the integration of active and passive device may be achieved in such miniaturized semiconductor package 10. Moreover, the conductive vias 850 of the redistribution structure 800 are directly connected to the conductive pads 120 of the semiconductor die 100, thereby forming a fan-out structure semiconductor die 100 without solder bumps on the conductive pads 120. In addition, the redistribution structure 800 directly connected to the semiconductor die 100 and the passive component 400 may keep a short conductivity path in order to improve electrical performance.

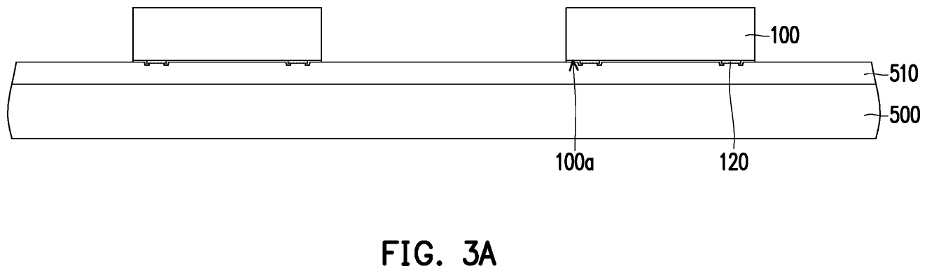

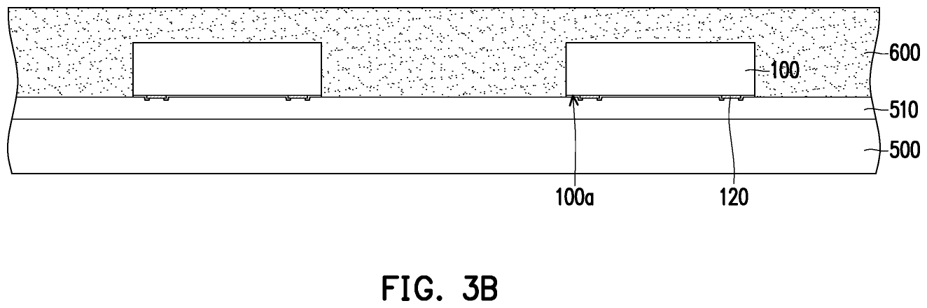

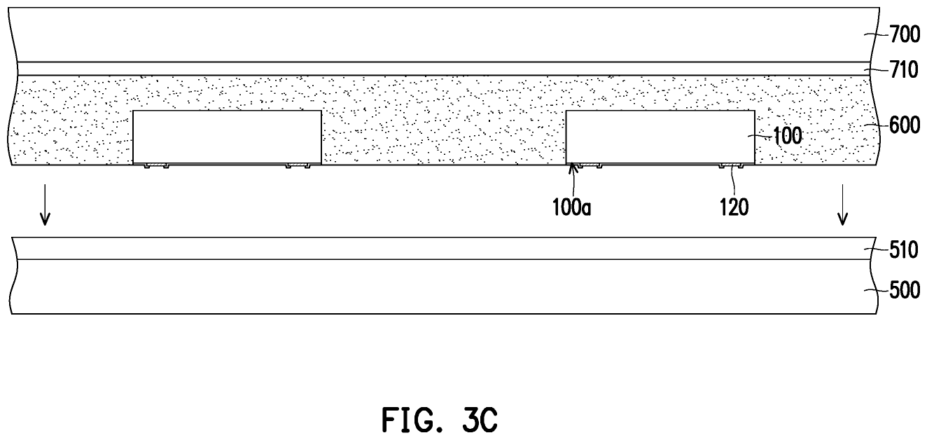

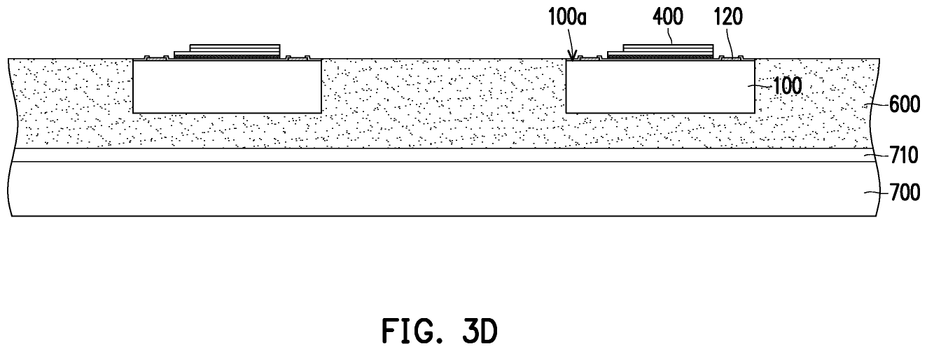

FIGS. 3A to 3D are cross-sectional views illustrating alternative steps of a manufacturing method of a semiconductor package according to an embodiment of the disclosure. The manufacturing method of the present embodiment is similar to the embodiment illustrated above. The identical or similar numbers refer to the identical or similar elements throughout the drawings, and detail thereof is not repeated. The difference between the present embodiment and the aforementioned embodiment is that the passive component 400 may be disposed on the active surface 100a of the semiconductor die 100 after the first temporary carrier 500 has been removed.

For example, referring to FIG. 3A, the semiconductor wafer 1000 shown in FIG. 1A may be provided and then singulated to form the individual semiconductor dies 100. After singulation, the semiconductor dies 100 may be disposed on the first temporary carrier 500 with the active surfaces 100a of the semiconductor dies 100 facing toward the first temporary carrier 500. In some embodiments, the conductive pads 120 of the semiconductor die 100 may be covered by the release layer 510.

Referring to FIG. 3B, after disposing the semiconductor die 100, the insulating encapsulant 600 may be formed on the first temporary carrier 500 to encapsulant the semiconductor die 100. The forming process of the insulating encapsulant 600 may be similar as that of described in FIG. 2C and the detailed descriptions are omitted for brevity.

Referring to FIG. 3C, the second temporary carrier 700 may be provided on the insulating encapsulant 600 opposite to the active surface 100a of the semiconductor die 100. In some embodiments, the second release layer 710 may be disposed between the second temporary carrier 700 and the insulating encapsulant 600. The process may be similar as that of described in FIG. 2D and the detailed descriptions are omitted for brevity. In some embodiments, the first temporary carrier 500 may be removed from the insulating encapsulant 600 to expose the active surface 100a of the semiconductor die 100.

Referring to FIG. 3D, after removing the first temporary carrier 500, the passive component 400 is disposed on the active surface 100a of the semiconductor die 100 without covering the conductive pads 120. The subsequent manufacturing process of the semiconductor package may be similar as described in FIGS. 2F to 2I, and the detailed descriptions are omitted for brevity.

Based on the foregoing, the passive component disposed on the active surface of the semiconductor die is embedded in the fan-out redistribution structure and electrically coupled to the semiconductor die and the redistribution structure, thereby achieving the integration of active and passive device in such compact semiconductor package. Moreover, the redistribution structure directly connected to the semiconductor die and the passive component may keep a short conductivity path in order to improve electrical performance. Accordingly, the semiconductor package may be compatible with high-end device applications.

It will be apparent to those skilled in the art that various modifications and variations can be made to the embodiments and concepts disclosed herein without departing from the scope or spirit of the invention. In view of the foregoing, it is intended that the present disclosure cover modifications and variations of this invention provided they fall within the scope of the following claims and their equivalents.

1. A semiconductor package, comprising:
a semiconductor die comprising an active surface and a plurality of conductive pads disposed on the active surface;
an insulating encapsulant encapsulating the semiconductor die and exposing the active surface of the semiconductor die;
a passive component disposed on the active surface of the semiconductor die; and
a redistribution structure disposed on the active surface of the semiconductor die and electrically connected to the conductive pads of the semiconductor die and the passive component.

2. The semiconductor package according to claim 1, further comprising:
a plurality of conductive terminals disposed on the redistribution structure opposite to the semiconductor die and electrically coupled to the redistribution structure.

3. The semiconductor package according to claim 1, wherein the redistribution structure comprises:
a dielectric layer disposed on the active surface of the semiconductor die;
a plurality of first conductive vias embedded in the dielectric layer and connected to the conductive pads of the semiconductor die; and
a conductive pattern disposed on the dielectric layer and electrically coupled to the first conductive vias.

4. The semiconductor package according to claim 3, wherein the dielectric layer comprises a plurality of first openings exposing at least a portion of the conductive pads of the semiconductor die, and the first conductive vias are disposed in the first openings of the dielectric layer.

5. The semiconductor package according to claim 3, wherein the passive component is embedded in the dielectric layer of the redistribution structure.

6. The semiconductor package according to claim 5, wherein the redistribution structure further comprises a plurality of second conductive vias, the dielectric layer further comprises a plurality of second openings exposing at least a portion of the passive component, and the second conductive vias are disposed in the second openings of the dielectric layer to electrically couple to the passive component.

7. The semiconductor package according to claim 1, wherein a surface of the insulating encapsulant is coplanar with the active surface of the semiconductor die.

8. The semiconductor package according to claim 1, wherein the passive component is disposed in a region of the active surface free of the conductive pads.

9. A manufacturing method of a semiconductor package, comprising:
disposing a passive component on an active surface of a semiconductor die, wherein the semiconductor die comprises a plurality of conductive pads disposed on the active surface;
encapsulating the semiconductor die with an insulating encapsulant, wherein the insulating encapsulant exposes the active surface of the semiconductor die; and
forming a redistribution structure on the active surface of the semiconductor die, wherein the redistribution structure is electrically connected to the conductive pads of the semiconductor die and the passive component.

10. The manufacturing method according to claim 9, further comprising:
forming a plurality of conductive terminals on the redistribution structure opposite to the semiconductor die to electrically couple to the redistribution structure.

11. The manufacturing method according to claim 9, wherein forming the redistribution structure comprises:
forming a dielectric layer on the active surface of the semiconductor die;
forming a plurality of first conductive vias in the dielectric layer to connect the conductive pads of the semiconductor die; and
forming a conductive pattern on the dielectric layer to electrically couple to the first conductive vias.

12. The manufacturing method according to claim 11, wherein after forming the dielectric layer, a plurality of first openings are formed in the dielectric layer to expose at least a portion of the conductive pads of the semiconductor die, and then the first conductive vias are formed in the first openings of the dielectric layer.

13. The manufacturing method according to claim 12, wherein after forming the dielectric layer, a plurality of second openings are formed in the dielectric layer to expose at least a portion of the passive component, and forming the redistribution structure further comprises forming a plurality of second conductive vias in the second openings to electrically couple to the passive component.

14. The manufacturing method according to claim 9, further comprising:
forming a release layer on a first temporary carrier;
disposing the semiconductor die on the first temporary carrier after disposing the passive component on the semiconductor die, wherein the passive component is embedded in the release layer; and
removing the first temporary carrier after encapsulating the semiconductor die with the insulating encapsulant, wherein a surface of the insulating encapsulant is coplanar with the active surface of the semiconductor die after removing the first temporary carrier.

15. The manufacturing method according to claim 9, further comprising:
forming a release layer on a first temporary carrier;
disposing the semiconductor die on the first temporary carrier before encapsulating the semiconductor die, wherein the active surface of the semiconductor die is in contact with the release layer; and
removing the first temporary carrier after encapsulating the semiconductor die to expose the active surface of the semiconductor die, wherein a surface of the insulating encapsulant is coplanar with the active surface of the semiconductor die after removing the first temporary carrier, and the passive component is disposed on the semiconductor die after the first temporary carrier is removed.

16. The manufacturing method according to claim 9, further comprising:
providing a second temporary carrier on the insulating encapsulant opposite to the active surface of the semiconductor die after encapsulating the semiconductor die with the insulating encapsulant; and
removing the second temporary carrier after forming the redistribution structure.

17. The manufacturing method according to claim 9, wherein disposing the passive component on the semiconductor die comprises:
attaching the passive component on the active surface of the semiconductor die through an adhesive layer.

18. The manufacturing method according to claim 9, further comprising:
providing a semiconductor wafer; and
singulating the semiconductor wafer to form a plurality of the semiconductor dies.

19. The manufacturing method according to claim 18, wherein the passive component is disposed on the semiconductor wafer before singulation.

20. The manufacturing method according to claim 18, further comprising:
reducing a thickness of the semiconductor wafer before singulation.
